(19) United States
(12) Patent Application Publication
(10) Pub. No.: US 2025/0156805 A1
(43) Pub. Date: May 15, 2025

(54) Transport Facility

(71) Applicant: Daifuku Co., Ltd., Osaka-shi (JP)

(72) Inventors: Kengo Ikedo, Komaki-shi (JP); Hiroshi Hayakawa, Komaki-shi (JP)

(21) Appl. No.: 18/940,965

(22) Filed: Nov. 8, 2024

(30) Foreign Application Priority Data
Nov. 10, 2023 (JP) 2023-192083

(51) Int. Cl. G06Q 10/087

(52) U.S. Cl. CPC G06Q 10/087

(57) ABSTRACT

A transport facility includes a plurality of transport vehicles and a control system. The control system updates, when a target article is transported from a transport source to a transport destination through a relay using two of the plurality of transport vehicles, an arrival prediction time at which the target article arrives at a receiving position in the relay based on a checkpoint pass time at which the target article passes a checkpoint, and deploys a second transport vehicle to be at the receiving position at the updated prediction time.

### CROSS-REFERENCE TO RELATED APPLICATION

This application claims priority to Japanese Patent Application No. 2023-192083 filed Nov. 10, 2023, the disclosure of which is hereby incorporated by reference in its entirety.

### BACKGROUND OF THE INVENTION

### Field of the Invention

The present invention relates to a transport facility.

### Description of Related Art

Transport facilities including multiple transport vehicles for transporting articles and a control system for controlling the transport vehicles are available. An example of such a transport facility is described in Japanese Unexamined Patent Application Publication No. 2020-101846 (JP 2020-101846).

The transport facility described in JP 2020-101846 predicts the time at which a target article is ready for transportation with a transport vehicle, and deploys a transport vehicle to be at a destination to receive the target article at the predicted time. This structure allows the target article to be transported immediately in response to the target article being ready for transportation, thus increasing the transport efficiency.

However, after the time at which the target article is ready for transportation is predicted, the time at which the target article is actually ready for transportation may deviate from the predicted time under certain circumstances. For example, a crowded or congested movement path or a partly closed movement path for the transport vehicle may delay the time at which the target article is actually ready for transportation from the predicted time. Conversely, the transport vehicle in another case may unexpectedly move smoothly along the movement path. The time at which the target article is actually ready for transportation may then be earlier than the predicted time.

In the first case, the transport vehicle that receives the target article waits until the target article actually arrives. This decreases the transport efficiency of the entire facility. In the second case, the target article cannot be transported until the transport vehicle arrives to receive the target article, although the target article has already arrived. This also decreases the transport efficiency.

### SUMMARY OF THE INVENTION

One or more aspects described herein are directed to a transport facility with a higher transport efficiency for transporting articles using multiple transport vehicles.

A transport facility according to an aspect of the disclosure includes a plurality of transport vehicles that transport articles and a control system that controls the plurality of transport vehicles. The control system performs, when a target article among the articles is transported from a transport source to a transport destination through a relay using two of the plurality of transport vehicles, a transport vehicle determination process, a path determination process, an initial prediction process, an update prediction process, and a receiving movement process. The transport vehicle determination process determines a first transport vehicle to transport the target article from the transport source to the relay and a second transport vehicle to transport the target article from the relay to the transport destination. The path determination process determines a first movement path for the first transport vehicle to move from a current position of the first transport vehicle to the relay through the transport source and a second movement path for the second transport vehicle to move from a current position of the second transport vehicle to the transport destination through the relay. The initial prediction process derives, based on the first movement path, an arrival prediction time as an initial prediction time. The arrival prediction time is a prediction time at which the target article arrives at a receiving position at which the second transport vehicle receives the target article in the relay. The update prediction process obtains a checkpoint pass time at which the target article passes a checkpoint set at least at one position along the first movement path and derives an updated prediction time being the arrival prediction time updated based on the checkpoint pass time. The receiving movement process causes, based on the initial prediction time before the updated prediction time is derived and based on the updated prediction time after the updated prediction time is derived, the second transport vehicle to arrive at the receiving position at a prediction time at which the target article arrives at the receiving position.

In this structure, when the target article is transported from the transport source to the transport destination using the two transport vehicles, the initial prediction process and the receiving movement process are performed to deploy the second transport vehicle to be at the receiving position at the initial prediction time at which the target article arrives at the receiving position in the relay. Thus, the target article can be immediately transported with the second transport vehicle immediately after the target article arrives at the receiving position in the relay. The update prediction process is further performed, and the receiving movement process is then performed using the updated prediction time derived through the update prediction process to deploy the second transport vehicle to be at the receiving position at the updated prediction time. Thus, any deviation of the time at which the first transport vehicle passes the checkpoint from the initial prediction time can be corrected to allow the target article to be transported with the second transport vehicle immediately after the target article arrives at the receiving position in the relay. This structure thus has a higher transport efficiency for transporting the articles using the plurality of transport vehicles.

Further features and advantageous effects of the technique according to the disclosure will be apparent from exemplary and nonlimiting embodiments described below with reference to the drawings.

### BRIEF DESCRIPTION OF THE DRAWINGS

The terms Fig., Figs., Figure, and Figures are used interchangeably in the specification to refer to the corresponding figures in the drawings.

FIG. 1 is a schematic diagram of a transport facility showing its overall structure.

FIG. 2 is a block diagram of a control system.

FIG. 3 is a diagram describing a procedure for processes performed in the control system.

FIG. 4 is a flowchart of a receiving movement process showing its procedure.

FIG. 5 is a schematic diagram of an example receiving movement process.

FIG. 6 is a schematic diagram of an example receiving movement process.

FIG. 7 is a schematic diagram of an example receiving movement process.

FIG. 8 is a schematic diagram of an example receiving movement process.

FIG. 9 is a schematic diagram of a transport facility according to another embodiment showing its overall structure.

### DESCRIPTION OF THE INVENTION

A transport facility according to one or more embodiments will now be described with reference to the drawings. A transport facility 1 according to the present embodiment is a facility (article transport facility) in which multiple articles W are transported. The transport facility 1 includes multiple transport vehicles 2 that transport the articles W. The articles W handled in the transport facility 1 and transported by the transport vehicles 2 include various items. For the transport facility 1 used in a semiconductor manufacturing plant, for example, the articles W are wafer containers (front opening unified pods, or FOUPs) containing wafers or reticle containers (reticle pods) containing reticles.

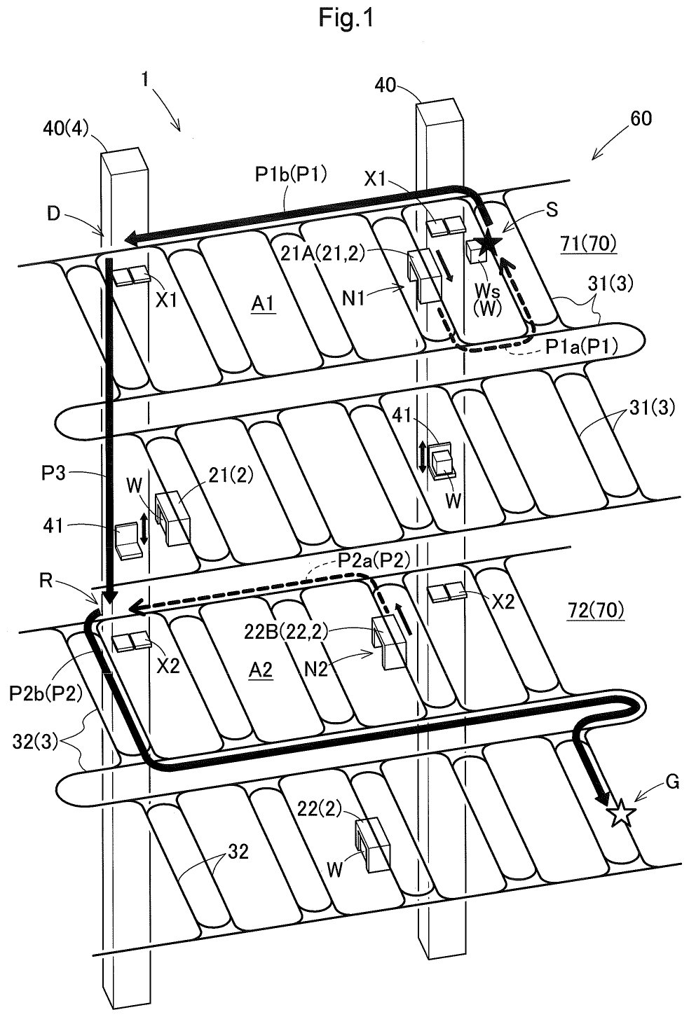

As shown in FIG. 1, the transport facility 1 according to the present embodiment transports the articles W between multiple areas including at least a first area A1 and a second area A2. In the present embodiment, the transport facility 1 is installed in a building 60 with multiple floors 70 including a first floor 71 and a second floor 72. In this case, the first floor 71 includes the first area A1, and the second floor 72 includes the second area A2. Although the second floor 72 is a floor 70 lower than the first floor 71 in the illustrated example, the second floor 72 may be a floor 70 upper than the first floor 71.

Each transport vehicle 2 travels along a travel path 3. In the present embodiment, the travel path 3 is defined by a travel rail hung from the ceiling. In other words, the transport vehicles 2 in the present embodiment are ceiling-hung transport vehicles. Each transport vehicle 2 includes a traveler that travels along the travel rail and a transferrer hung from the traveler.

The transport facility 1 according to the present embodiment includes multiple first-area transport vehicles 21 that travel along a first-area travel path 31 defined in the first area A1 and multiple second-area transport vehicles 22 that travel along a second-area travel path 32 defined in the second area A2. The transport facility 1 further includes inter-area transporters 40 that transport the articles W between the first area A1 and the second area A2. As described above, the first floor 71 includes the first area A1, and the second floor 72 includes the second area A2 in the present embodiment. The inter-area transporters 40 in the present embodiment are inter-floor transporters. In the present embodiment, each inter-area transporter 40 corresponds to a transporter.

Each inter-area transporter 40 includes a lifter 41 that holds and raises or lowers an article W. The lifter 41 supports and holds the article W from below. The lifter 41 is driven to be raised or lowered with a lift assembly (e.g., an assembly for raising or lowering the lifter 41 by winding or unwinding a belt) to raise or lower the article W. The inter-area transporter 40 (lifter 41) transports the article W between a first delivery position X1 in the first area A1 and a second delivery position X2 in the second area A2. In the present embodiment, multiple inter-area transporters 40 connect the first area A1 and the second area A2 at multiple positions.

In the transport facility 1, a specific one of the multiple articles W (referred to as a target article Ws in the present embodiment) is transported from a transport source S to a transport destination G. In the transport facility 1, two transport vehicles 2 (specifically, a single first-area transport vehicle 21 and a single second-area transport vehicle 22) transport the target article Ws from the transport source S to the transport destination G through a relay 4.

As described above, the transport facility 1 includes the multiple first-area transport vehicles 21 that transport the articles W in the first area A1 and the multiple second-area transport vehicles 22 that transport the articles W in the second area A2. For a target article Ws among the multiple articles W, a specific one of the multiple first-area transport vehicles 21 that transports the target article Ws in the first area A1 is referred to as a first transport vehicle 21A in the present embodiment. Similarly, a specific one of the multiple second-area transport vehicles 22 that transports the target article Ws in the second area A2 is referred to as a second transport vehicle 22B in the present embodiment.

The transport source S (a source for transporting the target article Ws) and the transport destination G (a destination for transporting the target article Ws) may each be, for example, a section of a storage shelf for storing the articles W or a load port in a processing device.

The relay 4 is a device for relaying transportation of the target article Ws between the first transport vehicle 21A and the second transport vehicle 22B. When the first transport vehicle 21A and the second transport vehicle 22B transport the target article Ws on the different floors 70 as in the present embodiment, one of the multiple inter-area transporters 40 serves as the relay 4. In this case, the relay 4 (inter-area transporter 40) transports the target article Ws between the floors 70 from a transfer position D for the first transport vehicle 21A in the first area A1 (first floor 71) to a receiving position R for the second transport vehicle 22B in the second area A2 (second floor 72).

The transfer position D for the first transport vehicle 21A to transfer the target article Ws is the first delivery position X1 in the inter-area transporter 40 serving as the relay 4. The receiving position R for the second transport vehicle 22B to receive the target article Ws is the second delivery position X2 in the inter-area transporter 40.

The transport facility 1 includes a control system 5 that controls at least the multiple transport vehicles 2. In the present embodiment, the control system 5 controls the multiple transport vehicles 2 and the multiple inter-area transporters 40 in the transport facility 1 including the multiple transport vehicles 2 and the multiple inter-area transporters 40. The control system 5 controls the multiple first-area transport vehicles 21, the multiple second-area transport vehicles 22, and the multiple inter-area transporters 40 in the transport facility 1 including the multiple first-area transport vehicles 21 and the multiple second-area transport vehicles 22 as the multiple transport vehicles 2.

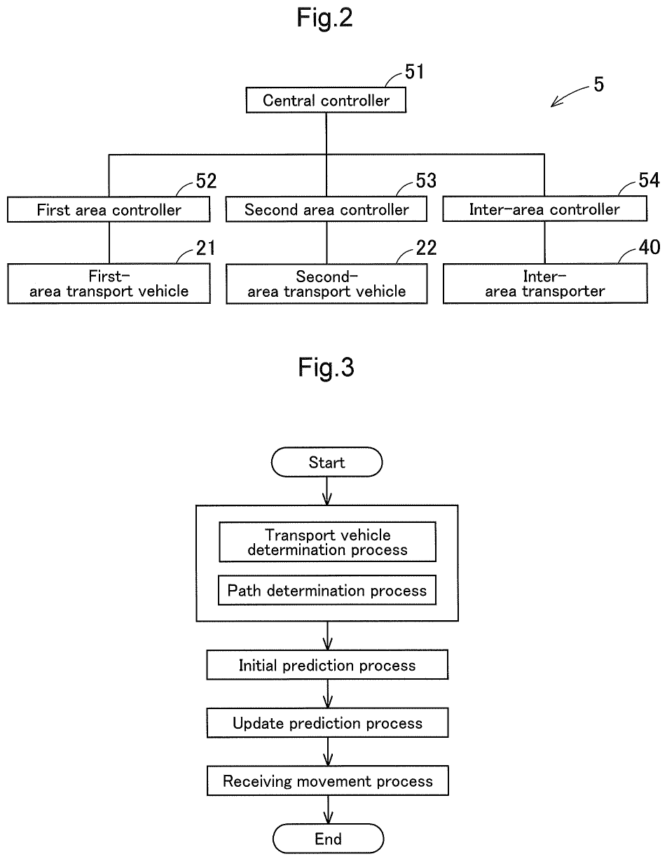

As shown in FIG. 2, the control system 5 includes a first area controller 52, a second area controller 53, and an inter-area controller 54. The first area controller 52 controls the operations of the multiple first-area transport vehicles 21. The second area controller 53 controls the operations of the multiple second-area transport vehicles 22. In the present embodiment, the first area controller 52 corresponds to a first controller, and the second area controller 53 corresponds to a second controller. The inter-area controller 54 controls the operations of the multiple inter-area transporters 40.

The control system 5 in the present embodiment further includes a central controller 51 in addition to the first area controller 52, the second area controller 53, and the inter-area controller 54. The central controller 51 centrally controls the first area controller 52, the second area controller 53, and the inter-area controller 54.

To transport the target article Ws from the transport source S to the transport destination G through the relay 4 using the two transport vehicles 2, the control system 5 performs a transport vehicle determination process, a path determination process, an initial prediction process, an update prediction process, and a receiving movement process as shown in FIG. 3.

The transport vehicle determination process determines the first transport vehicle 21A to transport the target article Ws from the transport source S to the relay 4 and the second transport vehicle 22B to transport the target article Ws from the relay 4 to the transport destination G. In the transport vehicle determination process, the control system 5 determines, among the multiple first-area transport vehicles 21, one first-area transport vehicle 21 optimal for transporting the target article Ws from the transport source S to the relay 4 to be the first transport vehicle 21A. Similarly, the control system 5 determines, among the multiple second-area transport vehicles 22, one second-area transport vehicle 22 optimal for transporting the target article Ws from the relay 4 to the transport destination G to be the second transport vehicle 22B.

The path determination process determines a first movement path P1 for the first transport vehicle 21A to move to the relay 4 and a second movement path P2 for the second transport vehicle 22B to move to the transport destination G. In the path determination process, the control system 5 determines an optimum path for the first transport vehicle 21A to move from a current position (referred to as a first current position N1) of the first transport vehicle 21A to the relay 4 through the transport source S to be the first movement path P1. In the same manner, the control system 5 determines an optimum path for the second transport vehicle 22B to move from a current position (referred to as a second current position N2) of the second transport vehicle 22B to the transport destination G through the relay 4 to be the second movement path P2.

The first movement path P1 includes a first preparation path P1a for an unloaded first transport vehicle 21A to move from the first current position N1 to the transport source S to receive the target article Ws, and a first transport path P1b for the first transport vehicle 21A that has received the target article Ws to move from the transport source S to the transfer position D to transfer the target article Ws to the relay 4.

The second movement path P2 includes a second preparation path P2a for an unloaded second transport vehicle 22B to move from the second current position N2 to the receiving position R to receive the target article Ws from the relay 4, and a second transport path P2b for the second transport vehicle 22B that has received the target article Ws to move from the receiving position R to the transport destination G to transfer the target article Ws to the transport destination G.

The transport vehicle determination process and the path determination process may be performed at the same time, although one of the processes may be performed first and the other may be performed later. More specifically, the determination of the first transport vehicle 21A and the first movement path P1 and the determination of the second transport vehicle 22B and the second movement path P2 may be performed collectively based on the positions of the transport vehicles 2 and the conditions of the travel path 3 (e.g., the degree of congestion or a closed path) when the transport source S and the transport destination G for the target article Ws are determined.

To collectively perform the transport vehicle determination process and the path determination process as described above, the travel path 3 is identified with a group of nodes representing locations and links each connecting two nodes. Each node and each link store information about a traveling cost. A combination that minimizes the traveling cost is then calculated using, for example, Dijkstra's algorithm.

In the present embodiment, the control system 5 also determines, in the path determination process, a path for transporting the target article Ws from the first floor 71 to the second floor 72 to be an inter-area movement path P3. When the first movement path P1 and the second movement path P2 are determined to minimize the traveling cost, the inter-area transporter 40 to be used is also determined automatically. The inter-area transporter 40 serves as the relay 4. The path from the first delivery position X1 (transfer position D) to the second delivery position X2 (receiving position R) for the inter-area transporter 40 is determined to be the inter-area movement path P3.

The central controller 51 performs the transport vehicle determination process and the path determination process. The central controller 51 transmits information about the determined first transport vehicle 21A and first movement path P1 to the first area controller 52, transmits information about the determined second transport vehicle 22B and second movement path P2 to the second area controller 53, and transmits information about the determined relay 4 to the inter-area controller 54.

The initial prediction process derives, based on at least the first movement path P1, an arrival prediction time as an initial prediction time that is a prediction time at which the target article Ws arrives at the receiving position R in the relay 4. In the initial prediction process in the present embodiment, the control system 5 derives the initial prediction time based on the first movement path P1 and the inter-area movement path P3. More specifically, the control system 5 derives the initial prediction time based on a movement time for the first transport vehicle 21A to move from the first current position N1 on the first movement path P1 to the transfer position D and on a transport time for the inter-area transporter 40 to transport the target article Ws from the transfer position D to the receiving position R.

More specifically, the control system 5 derives, as the initial prediction time, the time after a first preparation time, a first transport time, and an inter-area transport time from the time at which the first transport vehicle 21A starts moving from the first current position N1 (hereafter, an initial time). The first preparation time hereafter refers to the time taken for the first transport vehicle 21A to travel along the first preparation path P1a from the first current position N1 to the transport source S to receive the target article Ws at the transport source S. The first transport time hereafter refers to the time taken for the first transport vehicle 21A that has received the target article Ws to travel along the first transport path P1b from the transport source S to the transfer position D and transfer the target article Ws to the relay 4 at the transfer position D. The inter-area transport time hereafter refers to the time taken for the relay 4 that has received the target article Ws to transport the target article Ws from the transfer position D to the receiving position R.

The initial prediction time may be derived based on, for example, the distance along the travel path 3, the structure of the travel path 3 (e.g., straight or curved, or branching or merging), the transfer time for the article W, and the degree of congestion (the number of other first-area transport vehicles 21 on the travel path 3). In some embodiments, the transport facility 1 may include, at the first delivery position X1, a buffer for temporarily storing the article W received from the first-area transport vehicle 21 until the article W is transported with the inter-area transporter 40. The transport facility 1 may further include, at the second delivery position X2, a buffer for temporarily storing the article W transported with the inter-area transporter 40 until the second-area transport vehicle 22 receives the article W. When such a buffer (e.g., a conveyor) is used, the degree of congestion of the buffer (the number of other articles W in the buffer) may be used to derive the initial prediction time.

The central controller 51 performs the initial prediction process. For example, the central controller 51 obtains information about pass times linked with the multiple nodes and the multiple links included in the first preparation path P1a and the first transport path P1b, and information about a pass time taken to pass the inter-area transporter 40 included in the relay 4. The central controller 51 then performs the initial prediction process based on the obtained information. The central controller 51 performs the initial prediction process and provides the derived initial prediction time to the second area controller 53.

The basic process of the receiving movement process will now be described before the update prediction process is described.

The basic receiving movement process causes, based on the initial prediction time derived through the initial prediction process, the second transport vehicle 22B to arrive at the receiving position R at a prediction time at which the target article Ws arrives at the receiving position R. In the basic receiving movement process, the prediction time at which the target article Ws arrives at the receiving position R is the initial prediction time. The control system 5 thus causes the second transport vehicle 22B to arrive at the receiving position R at the initial prediction time.

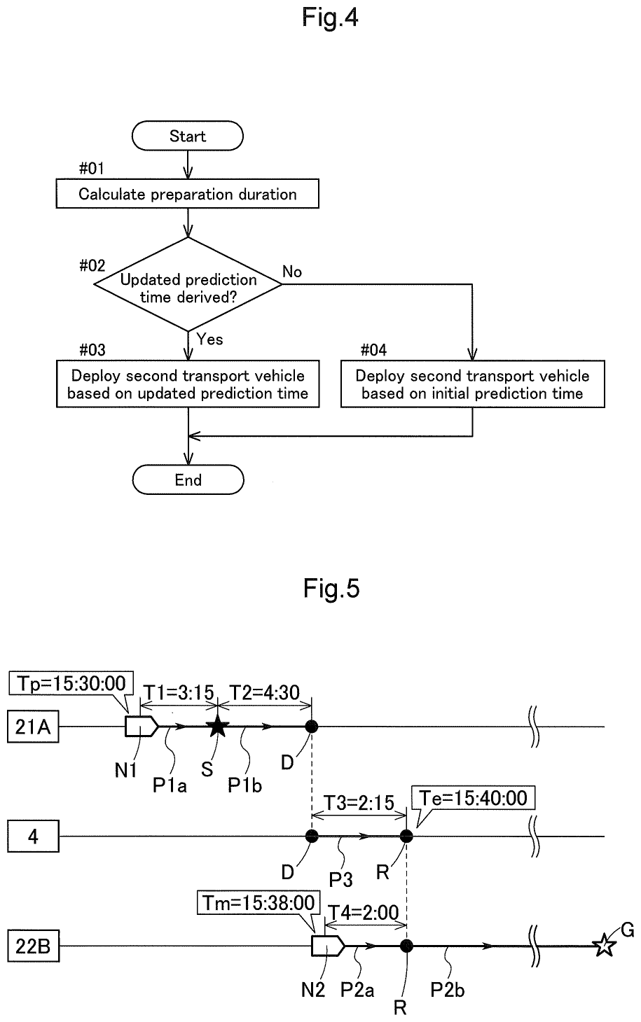

In the receiving movement process, the control system 5 derives a time taken for the second transport vehicle 22B to arrive at the receiving position R (hereafter, a preparation duration) based on the second preparation path P2a included in the second movement path P2 (step #01 in FIG. 4). The control system 5 derives the preparation duration as the time taken for the second transport vehicle 22B to travel along the second preparation path P2a from the second current position N2 to the receiving position R in the relay 4. In the present embodiment, the preparation duration corresponds to a duration.

In the present embodiment, the second area controller 53 calculates the preparation duration. The second area controller 53 obtains, for example, information about the pass times linked with the multiple nodes and the multiple links included in the second preparation path P2a, and calculates the preparation duration based on the obtained information.

The control system 5 causes the second transport vehicle 22B to move toward the receiving position R based on the current time reaching the time preceding the initial prediction time by the preparation duration. More specifically, when the current time reaches the time preceding the initial prediction time by the preparation duration, the control system 5 causes the second transport vehicle 22B to start moving from the second current position N2 toward the receiving position R. This allows, when the target article Ws is transported smoothly as initially predicted and reaches the receiving position R in the relay 4, the target article Ws to be transported immediately with the second transport vehicle 22B. Thus, simply performing the basic receiving movement process can increase the transport efficiency by a certain degree.

The update prediction process specific to the present embodiment and a receiving movement process improved further in the present embodiment will now be described.

The update prediction process obtains the time at which the target article Ws passes the checkpoint C set along the first movement path P1 (hereafter, a checkpoint pass time) and derives an updated prediction time that is an arrival prediction time updated based on the checkpoint pass time. The checkpoint C is set at least at one position along the first movement path P1. The checkpoint C may be set at a specific point on the first movement path P1, such as the transport source S, the transfer position D in the relay 4, or a branching point or a merging point on the first-area travel path 31.

The first area controller 52 obtains the information indicating the checkpoint pass time (hereafter, pass time information). The first area controller 52 can obtain the pass time information by, for example, reading a position information holder (e.g., a quick response or QR code or a radio-frequency identification or IC tag) at the checkpoint C with the corresponding reader installed on the first transport vehicle 21A or by performing image recognition on an image captured with a camera installed on the first floor 71. The first area controller 52 obtains the pass time information and transmits the obtained pass time information to the central controller 51.

In the update prediction process, the control system 5 derives the updated prediction time based on at least the checkpoint pass time and the movement time (hereafter, a post-checkpoint transport time) for the first transport vehicle 21A to move from the checkpoint C on the first movement path P1 to the transfer position D. In the transport facility 1 including the inter-area transporters 40 as in the present embodiment, the control system 5 derives the updated prediction time based on the checkpoint pass time, the post-checkpoint transport time, and a transport time (specifically, the inter-area transport time) for the inter-area transporter 40 to transport the target article Ws from the transfer position D to the receiving position R.

More specifically, the control system 5 derives, as the updated prediction time, the time after the post-checkpoint transport time and the inter-area transport time from the checkpoint pass time. This update prediction process corrects the prediction time at which the target article Ws arrives at the receiving position R to cancel any deviation of the time at which the first transport vehicle 21A passes the checkpoint C from the initial prediction time. When the first transport vehicle 21A passes the checkpoint C earlier than predicted by a predetermined time, the updated prediction time derived through the update prediction process is a time earlier by the predetermined time than the initial prediction time. Conversely, when the first transport vehicle 21A passes the checkpoint C later than predicted by a predetermined time, the derived updated prediction time is a time later by the predetermined time than the initial prediction time.

The central controller 51 performs the update prediction process. The central controller 51 performs the update prediction process to provide the derived updated prediction time to the second area controller 53, in the same manner as providing the initial prediction time.

In the receiving movement process described above, the control system 5 causes the second transport vehicle 22B to arrive at the receiving position R at the prediction time at which the target article Ws arrives at the receiving position R. After the updated prediction time is derived through the update prediction process (Yes in step #02 in FIG. 4), the updated prediction time is the corrected arrival prediction time at the receiving position R. The control system 5 thus causes the second transport vehicle 22B to arrive at the receiving position R at the updated prediction time.

The control system 5 causes the second transport vehicle 22B to move toward the receiving position R based on the current time reaching a time preceding the updated prediction time by the preparation duration (step #03). More specifically, when the current time reaches the time preceding the updated prediction time by the preparation duration, the control system 5 causes the second transport vehicle 22B to start moving from the second current position N2 toward the receiving position R. This can deploy the second transport vehicle 22B to be at the receiving position R at the time at which the target article Ws arrives at the receiving position R in the relay 4 although the arrival time deviates from the initial prediction time.

When, for example, the target article Ws arrives at the receiving position R earlier than predicted, the second transport vehicle 22B can be deployed earlier than initially predicted to immediately transport the target article Ws with the second transport vehicle 22B after the target article Ws arrives at the receiving position R. When, for example, the target article Ws arrives at the receiving position R later than predicted, the second transport vehicle 22B can be deployed later than initially predicted to use the waiting time for other purposes. Thus, the receiving movement process can increase the transport efficiency greatly.

In response to the current time reaching the time preceding the initial prediction time by the preparation duration before the updated prediction time is derived (No in step #02), the receiving movement process is performed as in the basic process. In this case, the control system 5 causes the second transport vehicle 22B to move toward the receiving position R based on the current time reaching a time preceding the initial prediction time by the preparation duration (step #04). When the current time reaches the time preceding the initial prediction time by the preparation duration, the control system 5 causes the second transport vehicle 22B to start moving from the second current position N2 toward the receiving position R.

The second area controller 53 performs the receiving movement process (in this example, a deployment process of the second transport vehicle 22B). The second area controller 53 performs the receiving movement process based on at least one of the initial prediction time or the updated prediction time received from the central controller 51.

More specific examples of the receiving movement process will now be described with reference to FIGS. 5 to 8. FIGS. 5 to 8 each show the target article Ws being transported by the first transport vehicle 21A in an upper part of the figure, the target article Ws being transported by the relay 4 in an intermediate part of the figure, and the target article Ws being transported by the second transport vehicle 22B in a lower part of the figure. The upper part also shows the movement of the first transport vehicle 21A. The lower part also shows the movement of the second transport vehicle 22B.

In these figures, Tp represents the initial time, Te represents the initial prediction time, Tc represents the checkpoint pass time, Tu represents the updated prediction time, and Tm represents a movement start time. Further, T1 represents the first preparation time, T2 represents the first transport time, T3 represents the inter-area transport time, and T4 represents the preparation duration. The transport source S and the transfer position D in the relay 4 are set as two checkpoints C in the figures.

FIG. 5 shows the movement of the target article Ws, the first transport vehicle 21A, and the second transport vehicle 22B initially predicted after the transport vehicle determination process, the path determination process, and the initial prediction process. The initial time is 15:30:00, the first preparation time is 3′15″, the first transport time is 4′30″, and the inter-area transport time is 2′15″ in the example. The initial prediction time is thus derived as 15:40:00, which is the time after the first preparation time, the first transport time, and the inter-area transport time (10 minutes later) from the initial time of 15:30:00. For the preparation duration being 2′00″, the movement start time is derived as 15:38:00, which is the time preceding the initial prediction time of 15:40:00 by the preparation duration (2′00″ before). When the current time reaches the movement start time, the second transport vehicle 22B starts moving.

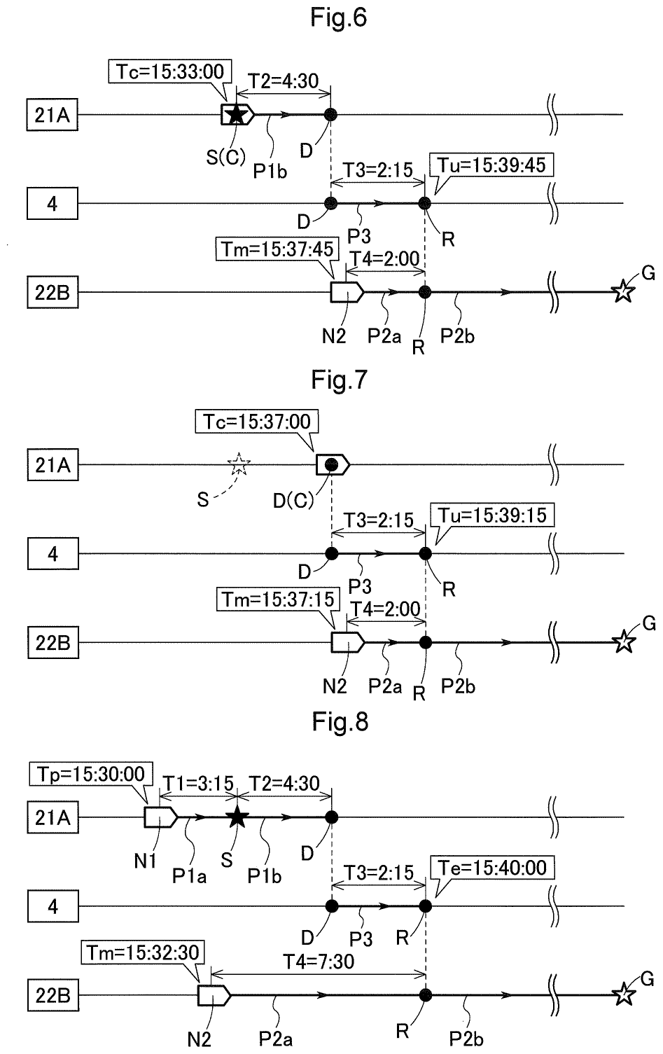

FIG. 6 shows the subsequent movement of the target article Ws and the transport vehicles when the actual arrival of the first transport vehicle 21A at the transport source S is earlier than initially predicted in the example in FIG. 5. In the illustrated example, the first preparation time is initially predicted to be 3′15″ (in other words, the first transport vehicle 21A is predicted to arrive at the transport source S at 15:33:15). However, the checkpoint pass time actually obtained at the transport source S indicates 15:33:00. In this case, the updated prediction time is derived as 15:39:45, which is the time after the first transport time and the inter-area transport time (6′45″ later) from the checkpoint pass time of 15:33:00 at the transport source S. The movement start time is derived as 15:37:45, which is the time preceding the updated prediction time of 15:39:45 by the preparation duration (2′00″ before). When the current time reaches the movement start time, the second transport vehicle 22B starts moving.

FIG. 7 shows the subsequent movement of the target article Ws and the transport vehicles when the actual arrival of the first transport vehicle 21A at the transfer position D is also earlier than initially predicted in the example in FIG. 6. In the illustrated example, the first preparation time is initially predicted to be 3′15″ and the first transport time to be 4′30″ (in other words, the first transport vehicle 21A is predicted to arrive at the transfer position D at 15:37:45). However, the checkpoint pass time actually obtained at the transfer position D indicates 15:37:00. In this case, the updated prediction time is derived as 15:39:15, which is the time after the inter-area transport time (2′15″ later) from the checkpoint pass time of 15:37:00 at the transfer position D. The movement start time is derived as 15:37:15, which is the time preceding the latest updated prediction time of 15:39:15 by the preparation duration (2′00″ before). When the current time reaches the movement start time, the second transport vehicle 22B starts moving.

In the examples in FIGS. 6 and 7, the time at which the second transport vehicle 22B starts moving is adjusted based on the actual pass times at the transport source S and the transfer position D. Thus, the second transport vehicle 22B arrives at the receiving position R when the target article Ws arrives at the receiving position R. Thus, the target article Ws can be immediately transported with the second transport vehicle 22B after the target article Ws arrives at the receiving position R. The unused waiting time at the receiving position R can be shortened by 15 seconds in the example in FIG. 6 and by 45 seconds in the example in FIG. 7, unlike when the receiving movement process is performed based on the initial prediction time alone without the update prediction process being performed. This increases the transport efficiency of the entire transport facility 1.

FIG. 8 shows the movement of the target article Ws and the transport vehicles when the current position (second current position N2) of the second transport vehicle 22B is far from the transfer position D in the relay 4 in the example in FIG. 5. In the present example, the preparation duration is 7′30″ for the distance from the second current position N2 to the transfer position D along the second-area travel path 32. In this case, the movement start time is derived as 15:32:30, which is the time preceding the initial prediction time of 15:40:00 by the preparation duration (7′30″ before). The movement start time is thus earlier than the arrival prediction time of about 15:33:15 at which the first transport vehicle 21A is predicted to arrive at the transport source S. In this case, the second transport vehicle 22B starts moving when the current time reaches the movement start time, without waiting for the arrival of the first transport vehicle 21A at the transport source S serving as the first checkpoint C.

### OTHER EMBODIMENTS

(1) In the receiving movement process in the embodiment described above, the control system 5 causes the second transport vehicle 22B to move toward the receiving position R when the current time reaches the time preceding the initial prediction time or the updated prediction time by the preparation duration. However, the structure is not limited to such an example. For example, the control system 5 may cause the second transport vehicle 22B to start moving toward the receiving position R shortly before the current time reaches the time preceding the initial prediction time or the updated prediction time by the preparation duration.

(2) In the transport vehicle determination process in the embodiment described above, the control system 5 mainly determines the second transport vehicle 22B among the second-area transport vehicles 22 stopped at the timing. However, the structure is not limited to such an example. The control system 5 may include, as a candidate for the second transport vehicle 22B, a second-area transport vehicle 22 that is currently moving but is scheduled to stop by the time preceding the initial prediction time by the preparation duration.

(3) In the embodiment described above with reference to FIGS. 5 to 8, the control system 5 mainly performs the update prediction process twice at the two checkpoints C, which are the transport source S and the transfer position D in the relay 4. However, the structure is not limited to such an example. The checkpoint C may be set at a single position alone, and the control system 5 may perform the update prediction process once. In some embodiments, the checkpoints C may be set at three or more positions, and the control system 5 may perform the update prediction process three or more times. The checkpoint C may not be set at the transport source S or the transfer position D, but may be set at another specific point (e.g., a branching point or a merging point on the first-area travel path 31) or at another non-specific point (any point on the first-area travel path 31).

(4) In the update prediction process in the above embodiment, the control system 5 derives, as the updated prediction time, the time after the post-checkpoint transport time and the inter-area transport time from the checkpoint pass time. However, the structure is not limited to such an example. For example, the control system 5 may calculate the time difference between the predicted pass time and the actual checkpoint pass time at the checkpoint C, and add the time difference to the initial prediction time or to the immediately preceding updated prediction time. The control system 5 may thus derive the latest updated prediction time. In some embodiments, the control system 5 may recalculate the post-checkpoint transport time and the inter-area transport time when the target article Ws arrives at the checkpoint C. The control system 5 may derive, as the latest updated prediction time, the time after the recalculated post-checkpoint transport time and the recalculated inter-area transport time from the checkpoint pass time.

(5) In the receiving movement process in the embodiment described above, the control system 5 allows the second transport vehicle 22B to move to the receiving position R after the second transport vehicle 22B starts moving based on the initial prediction time. However, the structure is not limited to such an example. The control system 5 may adjust, in response to the updated prediction time being derived after the second transport vehicle 22B starts moving based on the initial prediction time, the movement of the second transport vehicle 22B to the receiving position R based on the updated prediction time. In some embodiments, the control system 5 may perform, in response to the updated prediction time being derived after the second transport vehicle 22B starts moving based on the initial prediction time, the transport vehicle determination process for the second transport vehicle 22B again.

(6) In the embodiment described above, the second area controller 53 calculates the preparation duration. However, the structure is not limited to such an example. For example, the central controller 51 may calculate the preparation duration when deriving the initial prediction time.

(7) In the embodiment described above, the control system 5 includes the central controller 51 in an upper level and the first area controller 52, the second area controller 53, and the inter-area controller 54 in a lower level. However, the structure is not limited to such an example. The control system 5 may include a single controller in total. In some embodiments, the multiple transport vehicles 2 may include their controllers connected to one another to allow communication between them to together form the control system 5.

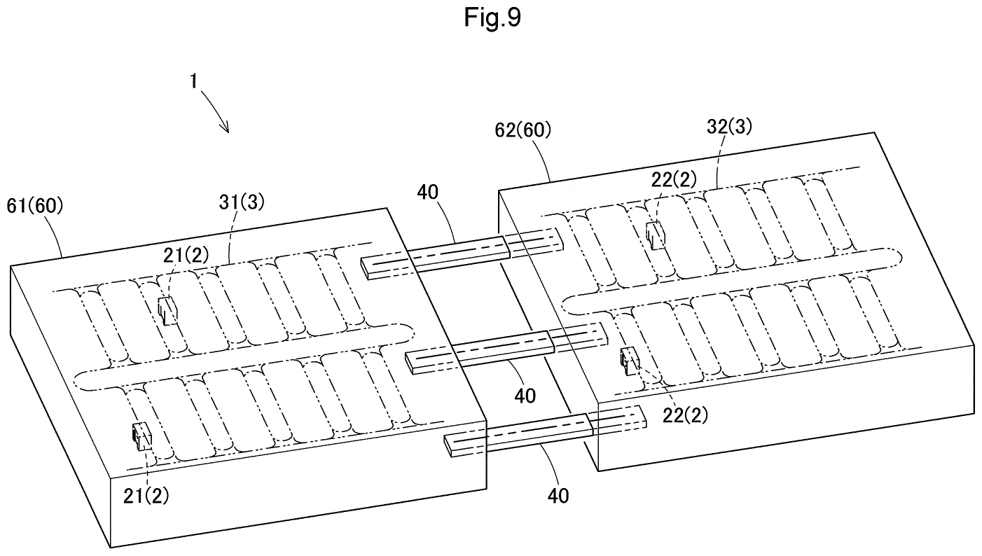

(8) In the embodiment described above, the transport facility 1 is installed in the building 60 with the multiple floors 70, and the inter-area transporters 40 serve as inter-floor transporters. However, the structure is not limited to such an example. As illustrated in, for example, FIG. 9, the transport facility 1 may be installed across multiple buildings 60 including a first building 61 and a second building 62. In this case, the inter-area transporters 40 may serve as inter-building transporters, and may include, for example, conveyors. The transport facility 1 may extend over multiple buildings 60 each including multiple floors 70. The inter-area transporters 40 may be combinations of inter-floor transporters and inter-building transporters.

(9) In the embodiment described above, the relays 4 are the inter-area transporters 40. However, the structure is not limited to such an example. For example, the relays 4 may be support devices that simply receive articles. In this structure, the position of each support device on which the article W is placed serves as the transfer position D and the receiving position R.

(10) In the embodiment described above, the transport facility 1 transports the target article Ws from the transport source S to the transport destination G through the single relay 4 using the two transport vehicles 2. However, the structure is not limited to such an example. The transport facility 1 may transport the target article Ws from the transport source S to the transport destination G using three or more transport vehicles 2. In this case, the relays 4 are fewer by one than the transport vehicles 2.

(11) The structures described in the above embodiments (including the above and other embodiments; the same applies hereafter) may be combined with the structures described in the other embodiments unless any contradiction arises. The embodiments described herein are mere examples in all respects and may be modified as appropriate without departing from the spirit and scope of the disclosure.

### Overview of Embodiment

The transport facility according to one or more embodiments of the disclosure may have the structure overviewed below.

A transport facility includes a plurality of transport vehicles that transport articles and a control system that controls the plurality of transport vehicles. The control system performs, when a target article among the articles is transported from a transport source to a transport destination through a relay using two of the plurality of transport vehicles, a transport vehicle determination process, a path determination process, an initial prediction process, an update prediction process, and a receiving movement process. The transport vehicle determination process determines a first transport vehicle to transport the target article from the transport source to the relay and a second transport vehicle to transport the target article from the relay to the transport destination. The path determination process determines a first movement path for the first transport vehicle to move from a current position of the first transport vehicle to the relay through the transport source and a second movement path for the second transport vehicle to move from a current position of the second transport vehicle to the transport destination through the relay. The initial prediction process derives, based on the first movement path, an arrival prediction time as an initial prediction time. The arrival prediction time is a prediction time at which the target article arrives at a receiving position at which the second transport vehicle receives the target article in the relay. The update prediction process obtains a checkpoint pass time at which the target article passes a checkpoint set at least at one position along the first movement path and derives an updated prediction time being the arrival prediction time updated based on the checkpoint pass time. The receiving movement process causes, based on the initial prediction time before the updated prediction time is derived and based on the updated prediction time after the updated prediction time is derived, the second transport vehicle to arrive at the receiving position at a prediction time at which the target article arrives at the receiving position.

In this structure, when the target article is transported from the transport source to the transport destination using the two transport vehicles, the initial prediction process and the receiving movement process are performed to deploy the second transport vehicle to be at the receiving position at the initial prediction time at which the target article arrives at the receiving position in the relay. Thus, the target article can be immediately transported with the second transport vehicle immediately after the target article arrives at the receiving position in the relay. The update prediction process is further performed, and the receiving movement process is then performed using the updated prediction time derived through the update prediction process to deploy the second transport vehicle to be at the receiving position at the updated prediction time. Thus, any deviation of the time at which the first transport vehicle passes the checkpoint from the initial prediction time can be corrected to allow the target article to be transported with the second transport vehicle immediately after the target article arrives at the receiving position in the relay. This structure thus has a higher transport efficiency for transporting the articles using the plurality of transport vehicles.

In one aspect, in the receiving movement process, the control system may derive a duration taken for the second transport vehicle to arrive at the receiving position based on a path from a current position of the second transport vehicle to the relay included in the second movement path. The control system may cause, in response to the updated prediction time being derived before a current time reaches a time preceding the initial prediction time by the duration, the second transport vehicle to move toward the receiving position based on the current time reaching a time preceding the updated prediction time by the duration.

This structure can cause, when the updated prediction time is derived, the second transport vehicle to start moving appropriately to be deployed at the receiving position at the time at which the target article arrives at the receiving position in the relay based on the updated prediction time and the duration.

In one aspect, in the receiving movement process, the control system may cause, in response to the current time reaching the time preceding the initial prediction time by the duration before the updated prediction time is derived, the second transport vehicle to move toward the receiving position based on the current time reaching the time preceding the initial prediction time by the duration.

This structure can cause, when the updated prediction time is not derived, the second transport vehicle to start moving appropriately to be deployed at the receiving position at the time at which the target article arrives at the receiving position in the relay based on the initial prediction time and the duration.

In one aspect, the relay may be a transporter that transports the target article from a transfer position at which the target article is transferred from the first transport vehicle to the receiving position. The control system may derive the initial prediction time based on a movement time for the first transport vehicle to move from a current position of the first transport vehicle on the first movement path to the transfer position and a transport time for the target article to be transported from the transfer position to the receiving position with the transporter. The control system may derive the updated prediction time based on the checkpoint pass time, a movement time for the first transport vehicle to move from the checkpoint to the transfer position on the first movement path, and a transport time for the target article to be transported from the transfer position to the receiving position with the transporter.

This structure can derive, for the relay that is a transporter for transporting an article, the initial prediction time and the updated prediction time appropriately based on the transport time for the transporter to transport the target article from the transfer position to the receiving position.

In one aspect, the first transport vehicle may transport the target article in a first area. The second transport vehicle may transport the target article in a second area. The relay may be an inter-area transporter that transports the target article between the first area and the second area. The control system may include a first controller that controls the plurality of transport vehicles in the first area, a second controller that controls the plurality of transport vehicles in the second area, and a central controller that controls the first controller and the second controller. The first controller may obtain pass time information indicating the checkpoint pass time and transmit the pass time information to the central controller. The central controller may perform the update prediction process and provide the derived updated prediction time to the second controller. The second controller may perform the receiving movement process based on the provided updated prediction time.

This structure allows the first controller, the second controller, and the central controller to cooperate with one another to appropriately control the transport vehicles in each area and the inter-area transporter when the articles are transported between the first area and the second area. The pass time information is exchanged between the first controller and the central controller, and the information about the updated prediction time is exchanged between the central controller and the second controller. The central controller centrally operates to cause the second controller to perform the receiving movement process appropriately.

The transport facility according to one or more embodiments of the disclosure produces at least one of the effects described above.

What is claimed is:

1. A transport facility, comprising:
a plurality of transport vehicles configured to transport articles; and
a control system configured to control the plurality of transport vehicles, the control system configured to perform, when a target article among the articles is transported from a transport source to a transport destination through a relay using two of the plurality of transport vehicles:
a transport vehicle determination process of determining a first transport vehicle to transport the target article from the transport source to the relay and a second transport vehicle to transport the target article from the relay to the transport destination,
a path determination process of determining a first movement path for the first transport vehicle to move from a current position of the first transport vehicle to the relay through the transport source and a second movement path for the second transport vehicle to move from a current position of the second transport vehicle to the transport destination through the relay,
an initial prediction process of deriving, based on the first movement path, an arrival prediction time as an initial prediction time, the arrival prediction time being a prediction time at which the target article arrives at a receiving position at which the second transport vehicle receives the target article in the relay,
an update prediction process of obtaining a checkpoint pass time at which the target article passes a checkpoint set at least at one position along the first movement path and deriving an updated prediction time being the arrival prediction time updated based on the checkpoint pass time, and
a receiving movement process of causing, based on the initial prediction time before the updated prediction time is derived and based on the updated prediction time after the updated prediction time is derived, the second transport vehicle to arrive at the receiving position at a prediction time at which the target article arrives at the receiving position.

2. The transport facility according to claim 1, wherein in the receiving movement process:
the control system derives a duration taken for the second transport vehicle to arrive at the receiving position based on a path from a current position of the second transport vehicle to the relay included in the second movement path, and
the control system causes, in response to the updated prediction time being derived before a current time reaches a time preceding the initial prediction time by the duration, the second transport vehicle to move toward the receiving position based on the current time reaching a time preceding the updated prediction time by the duration.

3. The transport facility according to claim 2, wherein in the receiving movement process:
the control system causes, in response to the current time reaching the time preceding the initial prediction time by the duration before the updated prediction time is derived, the second transport vehicle to move toward the receiving position based on the current time reaching the time preceding the initial prediction time by the duration.

4. The transport facility according to claim 1, wherein:
the relay is a transporter configured to transport the target article from a transfer position at which the target article is transferred from the first transport vehicle to the receiving position,
the control system derives the initial prediction time based on a movement time for the first transport vehicle to move from a current position of the first transport vehicle on the first movement path to the transfer position and a transport time for the target article to be transported from the transfer position to the receiving position with the transporter, and
the control system derives the updated prediction time based on the checkpoint pass time, a movement time for the first transport vehicle to move from the checkpoint to the transfer position on the first movement path, and a transport time for the target article to be transported from the transfer position to the receiving position with the transporter.

5. The transport facility according to claim 1, wherein:
the first transport vehicle transports the target article in a first area,
the second transport vehicle transports the target article in a second area,
the relay is an inter-area transporter configured to transport the target article between the first area and the second area,
the control system comprises a first controller configured to control the plurality of transport vehicles in the first area, a second controller configured to control the plurality of transport vehicles in the second area, and a central controller configured to control the first controller and the second controller,
the first controller obtains pass time information indicating the checkpoint pass time and transmits the pass time information to the central controller,
the central controller performs the update prediction process and provides the derived updated prediction time to the second controller, and
the second controller performs the receiving movement process based on the provided updated prediction time.
